(19) United States
(12) Patent Application Publication
(10) Pub. No.: US 2006/0022324 A1
(43) Pub. Date: Feb. 2, 2006

(54) Stacked flash memory chip package and method therefor

(75) Inventors: Gordon Yu, Taipei City (TW); Hung-Ya Liu, Yuanli Township (TW); Xeras Xiang, Hsinchu City (TW); Tsung-Kan Cheng, Taipei City (TW)

Correspondence Address: BACON & THOMAS, PLLC, 625 SLATERS LANE, FOURTH FLOOR, ALEXANDRIA, VA, 22314, US

(73) Assignee: C-One Technology Corporation, Hsin-Chu City (TW)

(21) Appl. No.: 11/024,440

(22) Filed: Dec. 30, 2004

(30) Foreign Application Priority Data
Jul. 28, 2004 (TW) 093122554

(51) Int. Cl. H01L 23/02

(52) U.S. Cl. 257/686

(57) ABSTRACT

This invention discloses a stacked flash memory chip package and a method for the stacked flash memory chip package. A first flash memory chip is mounted on a substrate, in which the first flash memory chip has an inactive surface for adhering to the substrate and a number of bond pads are all disposed on one side of an active surface of the flash memory chip. Then, a second flash memory chip is mounted over the first flash memory chip in a non-alignment manner so that the second flash memory chip shields part of the active surface of the first flash memory chip and that the bond pads of first flash memory chip are exposed. Then, the bond pads of the first flash memory chip and the bond pads of the second flash memory chip are respectively connected to the circuit of the substrate by wire bonding.

### BACKGROUND OF THE INVENTION

1. Field of the Invention

The present invention relates to an integrated circuit chip package, and more particularly, to a stacked flash memory chip package and a method for the stacked flash memory chip package.

2. Description of Related Art

An integrated circuit chip is generally encapsulated in a package to protect the chip and facilitate the carry and handle of the integrated circuit. FIG. 1 illustrates a ball grid array (BGA) integrated circuit package, in which a chip 11 is mounted on a substrate 12 beneath which a number of solder balls 13 are disposed. The chip 11 has an inactive surface for joining the substrate 12 and an active surface having bond pads 14 on both sides of the active surface. The bond pads 14 are connected to circuit 16 of the substrate 12 by means of bonding wires 15 so as to electrically connect to the solder balls 13. Finally, an encapsulant 17 is used to encapsulate the chip 11 and the bonding wires 15 so as to form an integrated circuit package.

To improve the density of the integrated circuit package, a package design which encapsulates two chips 111 and 112 in a stacked form is provided as illustrated in FIG. 2. To avoid the active surface of the chip 111 or 112 from being shielded as a result of the stacked arrangement, it is generally to put the inactive surfaces of the two chips 111 and 112 together (i.e., back-to-back attachment). As such, bond pads 21 of the lower chip 112 have to be directly mounted on the substrate 12, causing difficulty in electrically connecting to the substrate 12 by wire bonding. Hence, it is necessary to use a flip chip which, however, has a disadvantage of increased cost.

Therefore, it is desirable to provide an improved stacked flash memory chip package and a method for the stacked flash memory chip package to mitigate and/or obviate the aforementioned problems.

### SUMMARY OF THE INVENTION

A primary object of the present invention is to provide a stacked flash memory chip package and a method for the stacked flash memory chip package so as to present a low-cost and high-density chip package.

According to one aspect of the present invention, a method for stacked flash memory chip package provided by the present invention comprises the steps of: (A) providing a substrate having predetermined circuit; (B) mounting a first flash memory chip on the substrate, in which the first flash memory chip has an inactive surface for adhering to the substrate and a number of bond pads of the flash memory chip are all disposed on one side of an active surface of the first flash memory chip; (C) mounting a second flash memory chip on the first memory chip in a non-alignment manner so that the second flash memory chip shields only part of the active surface of the first flash memory chip and that the bond pads of the first flash memory chip are exposed, in which the second flash memory chip has an inactive surface for adhering to the first flash memory chip and a number of bond pads of the second flash memory chip are all disposed on one side of an active surface of the second flash memory chip; and (D) connecting the bond pads of the first flash memory chip and the bond pads of the second flash memory chip respectively to the circuit of the substrate by wire bonding.

According to another aspect of the present invention, a stacked flash memory chip package provided by the present invention comprises: a substrate having predetermined circuit; a first flash memory chip mounted on the substrate, in which the first flash memory chip has an inactive surface for adhering to the substrate and a number of bond pads of the flash memory chip are all disposed on one side of an active surface of the first flash memory chip; a second flash memory chip mounted on the first flash memory chip in a non-alignment manner so that the second flash memory chip shields only part of the active surface of the first flash memory chip and that the bond pads of the first flash memory chip are exposed, in which the second flash memory chip has an inactive surface for adhering to the first flash memory chip and a number of bond pads of the second flash memory chip are all disposed on one side of an active surface of the second flash memory chip; and bonding wires for connecting the bond pads of the first flash memory chip and the bond pads of the second flash memory chip respectively to the circuit of the substrate.

According to a further aspect of the present invention, a method for stacked flash memory chip package provided by the present invention comprises the steps of: (A) providing a substrate having predetermined circuit, in which part of the circuit are disposed at the inner periphery of the substrate and the other circuit are disposed at the outer periphery of the substrate; (B) mounting a control chip on the substrate, in which the control chip has a number of bond pads; (C) connecting the bond pads of the control chip to the circuit disposed at the inner periphery of the substrate by wire bonding; (D) filling an encapsulant into the substrate where the control chip is mounted to encapsulate the control chip and the bonding wires without shielding the circuit disposed at the outer periphery of the substrate, and then, curing the encapsulant; (E) mounting a flash memory chip on the encapsulant being cured, in which the flash memory chip has a number of bond pads; (F) connecting the bond pads of the flash memory chip to the circuit disposed at the outer periphery of the substrate by wire bonding; and (G) encapsulating the flash memory chip and the bonding wires with an encapsulant, and then, curing the encapsulant to become an integrated circuit package.

According to another aspect of the present invention, a stacked flash memory chip package provided by the present invention comprises: a substrate having predetermined circuit, in which part of the circuit are disposed at the inner periphery of the substrate and the other circuit are disposed at the outer periphery of the substrate; a control chip mounted on the substrate, in which the control chip has a number of bond pads; a flash memory chip mounted on the control chip, in which the flash memory chip has a number of bond pads; bonding wires for connecting not only the bond pads of the control chip to the circuit disposed at the inner periphery of the substrate but also the bond pads of the flash memory chip to the circuit disposed at the outer periphery of the substrate; and an encapsulant for encapsulating the control chip, the flash memory chip and the bonding wires.

Other objects, advantages, and novel features of the invention will become more apparent from the following detailed description when taken in conjunction with the accompanying drawings.

### BRIEF DESCRIPTION OF THE DRAWINGS

FIG. 1 is a configuration of a conventional BGA integrated circuit package.

FIG. 2 is a configuration of a conventional high-density integrate circuit package.

FIGS. 3A to 3F illustrate the steps of forming a stacked flash memory chip package according to a preferred embodiment of the present invention.

FIGS. 4A to 4H illustrate steps of forming a stacked flash memory chip package according to another preferred embodiment of the present invention.

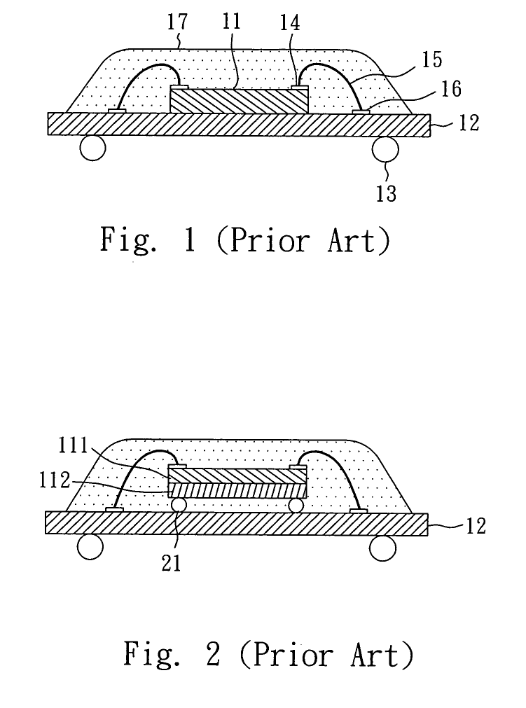

### DETAILED DESCRIPTION OF THE PREFERRED EMBODIMENT

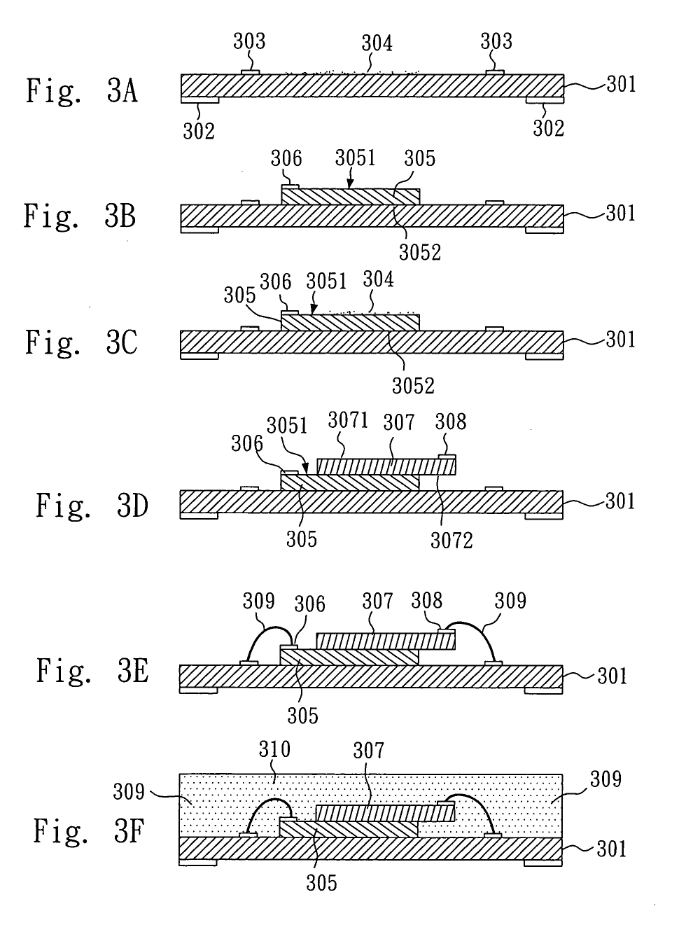

Referring to FIG. 3 illustrating a stacked flash memory chip package and a method for the stacked flash memory chip package according to a preferred embodiment of the present invention, in which FIGS. 3A to 3F shows the steps of forming such a stacked flash memory chip package.

As shown in FIG. 3A, a substrate 301 is provided. A number of connection pads 302 are disposed beneath both sides of the substrate 301 having predetermined circuit 303 for connecting to the connection pads 302. An elastomer 304 is printed on the central portion of the substrate 301.

As shown in FIG. 3B, a fist flash memory chip 305 is mounted on the elastomer 304 printed on the central portion of the substrate 301. The elastomer 304 is cured so that the first flash memory chip 305 is fixedly mounted on the substrate 301, in which the flash memory chip 305 has an inactive surface 3052 for adhering to the substrate 301 and a number of bond pads 306 of the flash memory chip 305 are all disposed on one side of an active surface 3051 of the flash memory chip 305. The flash memory chip 305 is an AG-AND type flash memory chip, for example.

As shown in FIG. 3C, the elastomer 304 is printed on the active surface 3051 of the first flash memory chip 305.

As shown in FIG. 3D, a second flash memory chip 307 is mounted over the elastomer 304 printed on the first flash memory chip 305. The elastomer 304 is cured so that the second flash memory chip 307 is fixedly mounted on the first flash memory chip 305, in which the second flash memory chip 307 is placed on the first flash memory chip 305 in a non-alignment manner so as to shield part of the active surface 3051 of the first flash memory chip 305 and expose the bond pads 306 of the first flash memory chip 305. In addition, the second flash memory chip 307 has an inactive surface 3072 for adhering to the first flash memory chip 305. Similarly, a number of bond pads 308 of the second flash memory chip 307 are all disposed on one side of an active surface 3071 of the second flash memory chip such as an AG-AND type flash memory chip; and also, the inactive surface 3072 of the second flash memory chip 307 is adhered to the active surface 3051 of the first flash memory chip 305. Thus, the bond pads 308 of the second flash memory chip 307 are opposed to the bond pads 306 of the first flash memory chip 305.

As shown in FIG. 3E, bonding wires 309 are used to connect the bond pads 306 of the first flash memory chip 305 and the bonds pads 308 of the second flash memory chip 307 to the circuit 303 of the substrate 301 respectively so as to further electrically connect to the connection pads 302.

As shown in FIG. 3F, the first and second flash memory chips 305, 307 and the bonding wires 309 are encapsulated with an encapsulant 310. The encapsulant 310 is then cured to become an integrated circuit package.

In the aforesaid integrated circuit package, the size is reduced because the first and second flash memory chips are stacked. Furthermore, because the bond pads 306, 308 of the first and second flash memory chips 305, 307 are oriented in the same direction (on the opposite side of the respective chips facing the substrate 301), it is easy for the bonding wires 309 to electrically connect the first and second flash memory chips 305, 307 to the substrate 301, dispensing with the need of a flip chip. Hence, the fabricating cost is effectively reduced.

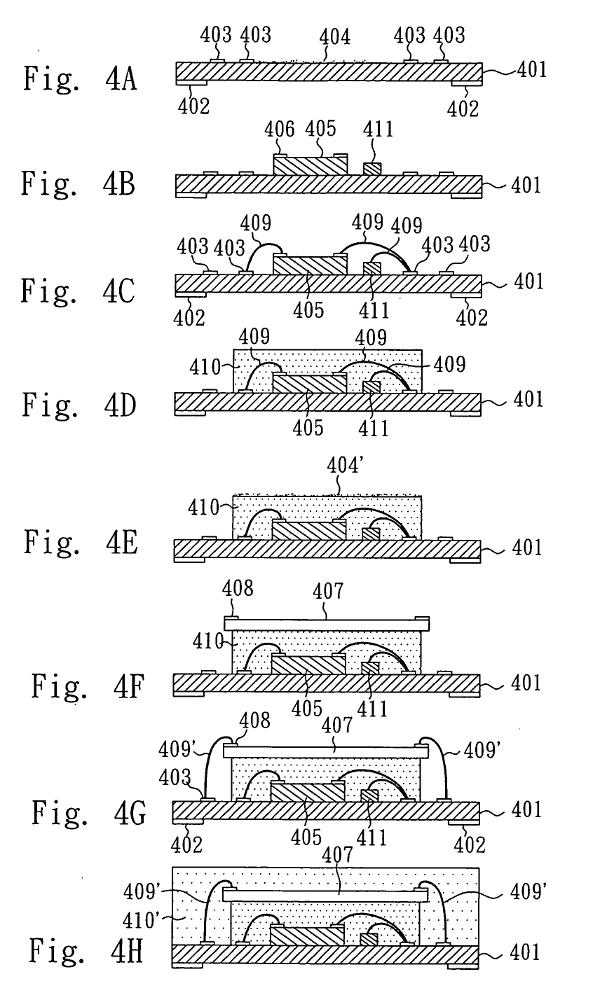

Referring next to FIG. 4 showing another preferred embodiment, in which FIGS. 4A to 4F illustrates the steps for forming such a stacked flash memory chip package.

As shown in FIG. 4A, a substrate 401 is provided. A number of bond pads 402 are disposed beneath both sides of the substrate 401 having predetermined circuit 403 for interconnecting and connecting to the bond pads 402, in which part of the circuit 403 are disposed at the inner periphery of the substrate 401 while the other circuit 403 are disposed at the outer periphery of the substrate 401. An elastomer 404 is printed on the central portion of the substrate 401.

As shown in FIG. 4B, a control chip 405 is mounted over the elastomer 404 printed on the substrate 401. The elastomer 404 is cured so that the control chip 405 is fixedly mounted on the substrate 401, in which the control chip 405 has a number of bond pads 406 disposed on both sides (or the periphery) thereof. In this step, another electronic component 411 can also be mounted on the substrate 401.

As shown in FIG. 4C, the bond pads 406 of the control chip 405 and the electronic component 411 are respectively connected to the circuit 403 disposed at the inner periphery of the substrate 401 with bonding wires 409 to further electrically connect to the bond pads 402.

As shown in FIG. 4D, an encapsulant 410 is filled into the substrate 401 where the control chip 405 is mounted so that only the control chip 405, the electronic component 411 and the bonding wires 409 are encapsulated without shielding the circuit 403 disposed at the outer periphery of the substrate 401 by the encapsulant 410. The encapsulant 410 is then cured.

As shown in FIG. 4E, an elastomer 404′ is printed on the encapsulant 410 being cured.

As shown in FIG. 4F, a flash memory chip 407 is mounted over the encapsulant 410 being cured with the printed elastomer 404′. The elastomer 404′ is cured so that the flash memory chip 407 is fixedly mounted on the control chip 405 and the electronic component 411. The flash memory chip 407 has a number of bond pads 408 disposed on both sides (or the periphery) thereof.

As shown in FIG. 4G, the bond pads 408 of the flash memory chip 407 are connected to the circuit 403 disposed at the outer periphery of the substrate 401 with bonding wires 409′ to further electrically connect to the bond pads 402, the control chip 405 and the electronic component 411.

As shown in FIG. 4H, the flash memory chip 407 and the bonding wires 409 are encapsulated with an encapsulant 410′. The encapsulant 410′ is cured to become an integrated circuit package.

In the aforesaid integrated circuit package, the size is reduced because the control chip 405 and the flash memory chip 407 are stacked. Furthermore, the flash memory chip 407 has a larger size than the control chip 405. The stack of the flash memory chip 407 over the control chip 405 allows connections of the bonding wires 409 of the control chip 405 and placement of the electronic component 411 to be limited to the area covered by the flash memory chip 407 so as to increase the area usage, as a whole. Moreover, it is easy for the bonding wires 409, 409′ to electrically connect the control chip 405 and the flash memory chip 407 to the substrate 401, dispensing with the need of a flip chip. Hence, the fabricating cost is effectively reduced.

Although the present invention has been explained in relation to its preferred embodiments, it is to be understood that many other possible modifications and variations can be made without departing from the spirit and scope of the invention as hereinafter claimed.

What is claimed is:

1. A method for stacked flash memory chip package, comprising the steps of:
(A) providing a substrate having predetermined circuit;
(B) mounting a first flash memory chip on said substrate, wherein said first flash memory chip has an inactive surface for adhering to said substrate and a number of bond pads of said flash memory chip are all disposed on one side of an active surface of said first flash memory chip;
(C) mounting a second flash memory chip on said first memory chip in a non-alignment manner so that said second flash memory chip shields only part of said active surface of said first flash memory chip and that said bond pads of said first flash memory chip are exposed, wherein said second flash memory chip has an inactive surface for adhering to said first flash memory chip and a number of bond pads of said second flash memory chip are all disposed on one side of an active surface of said second flash memory chip; and
(D) connecting said bond pads of said first flash memory chip and said bond pads of said second flash memory chip respectively to said circuit of said substrate by wire bonding.

2. The method of claim 1, wherein in step (B) said first flash memory chip is fixedly mounted on said substrate with an elastomer.

3. The method of claim 1, wherein in step (C) said second flash memory chip is fixedly mounted on said first flash memory with an elastomer.

4. The method of claim 1, further comprising step (E) of encapsulating said first and second flash memory chips and said bonding wires with an encapsulant and then curing the encapsulant to become an integrate circuit package.

5. The method of claim 4, wherein in step (A) a number of bond pads are mounted beneath said substrate for being connected to said circuit of said substrate.

6. A stacked flash memory chip package, comprising:
a substrate having predetermined circuit;
a first flash memory chip mounted on said substrate, wherein said first flash memory chip has an inactive surface for adhering to said substrate and a number of bond pads of said flash memory chip are all disposed on one side of an active surface of said first flash memory chip;
a second flash memory chip mounted on said first flash memory chip in a non-alignment manner so that said second flash memory chip shields only part of said active surface of said first flash memory chip and that said bond pads of said first flash memory chip are exposed, wherein said second flash memory chip has an inactive surface for adhering to said first flash memory chip and a number of bond pads of said second flash memory chip are all disposed on one side of an active surface of said second flash memory chip; and
bonding wires for connecting said bond pads of said first flash memory chip and said bond pads of said second flash memory chip respectively to said circuit of said substrate.

7. The stacked flash memory chip package of claim 6, further comprising an encapsulant for encapsulating said first and second flash memory chips and said bonding wires.

8. The stacked flash memory chip package of claim 6, wherein a number of bond pads are mounted beneath said substrate for being connected to said circuit of said substrate.

9. A method for stacked flash memory chip package, comprising the steps of:
(A) providing a substrate having predetermined circuit, wherein part of said circuit are disposed at the inner periphery of said substrate and the other circuit are disposed at the outer periphery of said substrate;
(B) mounting a control chip on said substrate, wherein said control chip has a number of bond pads;
(C) connecting said bond pads of said control chip to said circuit disposed at the inner periphery of said substrate by wire bonding;
(D) filling an encapsulant into said substrate, wherein said control chip is mounted to encapsulate said control chip and said bonding wires without shielding said circuit disposed at the outer periphery of said substrate, and then curing said encapsulant;
(E) mounting a flash memory chip on said encapsulant being cured, wherein said flash memory chip has a number of bond pads;
(F) connecting said bond pads of said flash memory chip to said circuit disposed at the outer periphery of said substrate by wire bonding; and
(G) encapsulating said flash memory chip and said bonding wires with an encapsulant, and then curing said encapsulant to become an integrated circuit package.

10. The method of claim 9, wherein in step (B) said control chip is fixedly mounted on said substrate with an elastomer.

11. The method of claim 9, wherein in step (E) said flash memory chip is fixedly mounted on said encapsulant being cured with an elastomer.

12. The method of claim 9, wherein in step (B) at least an electronic component mounted on said substrate is further included.

13. The method of claim 9, wherein in step (A) a number of bond pads are disposed beneath said substrate for being interconnected and connected to said circuit of said substrate.

14. A stacked flash memory chip package, comprising:
a substrate having predetermined circuit, wherein part of said circuit are disposed at the inner periphery of said substrate and the other circuit are disposed at the outer periphery of said substrate;
a control chip mounted on said substrate, wherein said control chip has a number of bond pads;
a flash memory chip mounted on said control chip, wherein said flash memory chip has a number of bond pads;
bonding wires for connecting not only said bond pads of said control chip to said circuit disposed at the inner periphery of said substrate but also said bond pads of said flash memory chip to said circuit disposed at the outer periphery of said substrate; and
an encapsulant for encapsulating said control chip, said flash memory chip and said bonding wires.

15. The stacked flash memory chip package of claim 14, further comprising at least an electronic component mounted over said substrate and beneath said flash memory chip.

16. The stacked flash memory chip package of claim 14, wherein a number of bond pads are disposed beneath said substrate for being interconnected and connected to said circuit of said substrate.
